(19) United States
(12) Patent Application Publication
(10) Pub. No.: US 2023/0299557 A1
(43) Pub. Date: Sep. 21, 2023

(54) LIGHT EMITTING DEVICE

(71) Applicant: NICHIA CORPORATION, Anan-shi (JP)

(72) Inventors: Takuya HASHIMOTO, Tokushima-shi (JP); Soichiro MIURA, Tokushima-shi (JP)

(73) Assignee: NICHIA CORPORATION, Anan-shi (JP)

(21) Appl. No.: 18/182,790

(22) Filed: Mar. 13, 2023

(30) Foreign Application Priority Data
Mar. 15, 2022 (JP) 2022-040826

(51) Int. Cl. H01S 5/0683; H01S 5/02257; H01S 5/40; H01S 5/02253; H01S 5/02255

(52) U.S. Cl. CPC H01S 5/0683; H01S 5/02257; H01S 5/4093; H01S 5/4031; H01S 5/02253; H01S 5/02255

(57) ABSTRACT

A light emitting device includes a first light-emitting element configured to emit a first light in a first direction, a second light-emitting element configured to emit a second light in the first direction, a package including a substrate and a cap, having a light emission surface through which the first light and second light emitted from the first and second light-emitting elements are passed, and forming a closed space in which the first and second light-emitting elements are located, one or more optical members that are spaced away from the light emission surface in the first direction, and that are configured to combine the first light and second light, and one or more photodetectors that are spaced away from the light emission surface in the first direction, and that are configured to receive the first light and second light.

### CROSS-REFERENCE TO RELATED APPLICATION

This application claims priority to Japanese Patent Application No. 2022-040826, filed on Mar. 15, 2022, the disclosure of which is hereby incorporated by reference in its entirety.

### BACKGROUND

The present disclosure relates to light emitting devices.

A known light emitting device includes a plurality of light-emitting elements, a photodetector for monitoring optical outputs emitted from the light-emitting elements, and a package in which the plurality of light-emitting elements and the photodetector are mounted. Japanese Patent Publication No. 2017-098301 describes an optical module including a plurality of laser diodes, a beam-combining optical system that combines a plurality of laser beams emitted from the plurality of laser diodes to produce a combined light beam, and a photodiode that detects the intensity of the combined light beam.

### SUMMARY

Provided is a light emitting device capable of monitoring the intensities of light emitted from each of a plurality of light-emitting elements separately.

In a non-limiting illustrative embodiment, a light emitting device according to the present disclosure includes a first light-emitting element to emit a first light in a first direction, a second light-emitting element to emit a second light in the first direction, a package including a substrate and a cap, having a light emission surface through which the first light and second light emitted from the first and second light-emitting elements are passed, and forming a closed space in which the first and second light-emitting elements are located, one or more optical members that are spaced away from the light emission surface in the first direction, and that combines the first light and second light, and one or more photodetectors that are spaced away from the light emission surface in the first direction, and that receives the first light and second light.

The light emitting device of the present disclosure is capable of monitoring the intensities of light emitted from each of a plurality of light-emitting elements separately.

### BRIEF DESCRIPTION OF THE DRAWINGS

FIG. 1 is a top view of a light emitting device according to a first embodiment of the present disclosure.

FIG. 2 is a top view of the light emitting device of the first embodiment of the present disclosure with a cap thereof removed.

FIG. 3 is a top view of the light emitting device of FIG. 2 with a reflection member thereof further removed.

FIG. 4 is a cross-sectional view taken along line IV-IV of FIG. 1.

FIG. 5 is a partially enlarged view of the cross-sectional view of FIG. 4 including a reflection member and a photodetector.

FIG. 6 is a cross-sectional view of a light emitting device further including another substrate.

FIG. 7 is a cross-sectional view of a light emitting device that is a variation of the light emitting device of the first embodiment of the present disclosure.

FIG. 8 is a top view of a light emitting device that is a variation of the light emitting device of the first embodiment of the present disclosure with a cap thereof removed.

FIG. 9 is a cross-sectional view of a light emitting device according to a second embodiment of the present disclosure.

FIG. 10 is a top view of the light emitting device of the second embodiment of the present disclosure with a cap thereof removed.

FIG. 11 is a partially enlarged view of the cross-sectional view of FIG. 9 including a reflection member and a photodetector.

FIG. 12 is a cross-sectional view of a light emitting device according to a third embodiment of the present disclosure.

FIG. 13 is a top view of the light emitting device of the third embodiment of the present disclosure with a cap thereof removed.

FIG. 14 is a cross-sectional view of light emitting devices according to a fourth to seventh embodiments of the present disclosure.

FIG. 15 is a top view of the light emitting device of the fourth embodiment of the present disclosure with a cap thereof removed.

FIG. 16 is a top view of the light emitting device of the fifth embodiment of the present disclosure with a cap thereof removed.

FIG. 17 is a top view of the light emitting device of the sixth embodiment of the present disclosure with a cap thereof removed.

FIG. 18 is a top view of the light emitting device of the seventh embodiment of the present disclosure with a cap thereof removed.

FIG. 19 is a cross-sectional view of a light emitting device according to an eighth embodiment of the present disclosure.

### DETAILED DESCRIPTION

In the specification and claims herein, a polygonal shape, such as a triangle, quadrangle, or the like, is not limited to the polygonal shape in a mathematically strict sense, and includes any of those shapes subjected to processing such as cutting angles, chamfering, beveling, rounding, or the like. Similarly, a polygonal shape subjected to processing not only at a corner (end of a side), but also in any intermediate portion of a side will also be referred to as a polygonal shape. In other words, any polygon-based shape subjected to processing is included in a “polygon” disclosed in the specification and the claims herein.

This applies to not only polygons, but also any word that describes a specific shape, such as a trapezoidal, circular, recessed, or projected shape. This also applies when describing each side of a shape. In other words, even if a side is subjected to processing at a corner or at a portion between corners, the “side” includes the processed portion. In the case of distinguishing a “polygon” or “side” that has not been processed from a processed shape, it will be expressed with the word “strict sense” added thereto, for example, a “strict sense quadrangle.”

In the specification and claims herein, moreover, when there are multiple pieces of a certain component and a distinction must be made, an ordinal such as “first,” “second,” or the like might occasionally be added. For example, a claim may recite that “two light emitting elements are disposed on a substrate,” while the specification may state that “a first light emitting element and a second light emitting element are disposed on a substrate.” The ordinals, such as “first” and “second,” are used to distinguish two light emitting elements. Elements having the same ordinal term and the same name between the description and the claims may not be the same element. For example, in the case in which elements are specified by the words, “a first light emitting element,” “a second light emitting element,” and “a third light emitting element,” in the specification, “a first light emitting element” and “a second light emitting element” recited in the claims might correspond to “a first light emitting element” and “a third light emitting element” in the specification. Furthermore, in the case in which the term, “a first light emitting element,” is used, but the term, “a second light emitting element,” is not used in claim 1, the invention according to claim 1 is sufficient if it includes one light emitting element, and the light emitting element is not limited to “a first light emitting element” as used in the specification, i.e., it can be “a second light emitting element” or “a third light emitting element” in the specification.

In the specification and claims herein, terms indicating directions or positions (e.g., “upper/upward,” “lower/downward,” “right/rightward,” “left/leftward,” “front,” and “rear”) might be used. These terms, however, are merely used for the purpose of making the relative directions or positions in the drawings being referenced more easily understood. As long as the relative relationship between the directions or the positions indicated with the terms such as “upper,” “lower,” or the like is the same as those in a referenced drawing, the absolute layout of the elements in drawings outside of the present disclosure, or actual products and manufacturing equipment outside of the present disclosure, does not have to be the same as that shown in the referenced drawing.

Note that the dimensions, dimensional ratio, shapes, interspace of arrangement, etc. of any component elements shown in a drawing may be exaggerated for ease of understanding. In order to avoid excessive complexity of the drawings, certain elements may be omitted from illustration.

Hereinafter, embodiments of the present invention will be described with reference to the drawings. Although the embodiments illustrate specific implementations of the technological concepts of the present invention, they do not limit the present invention. The numerical values, shapes, materials, steps, and the order of the steps shown in the description of the embodiments are only examples, and various modifications are possible so long as there is no technical contradiction. In the following description, elements identified by the same name or reference numerals are the same or the same type of elements, and redundant explanations of those elements may be omitted.

### First Embodiment

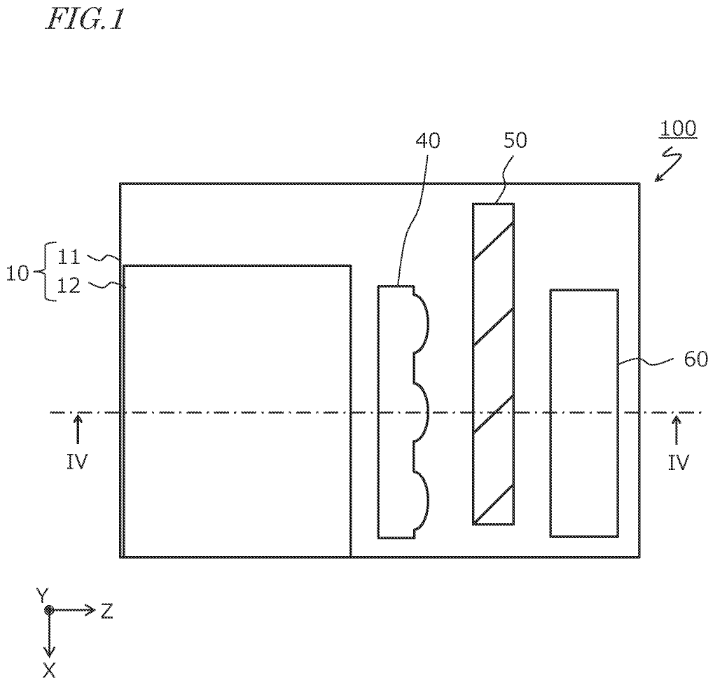

An example configuration of a light emitting device according to a first embodiment of the present disclosure will be described with reference to FIGS. 1 to 5.

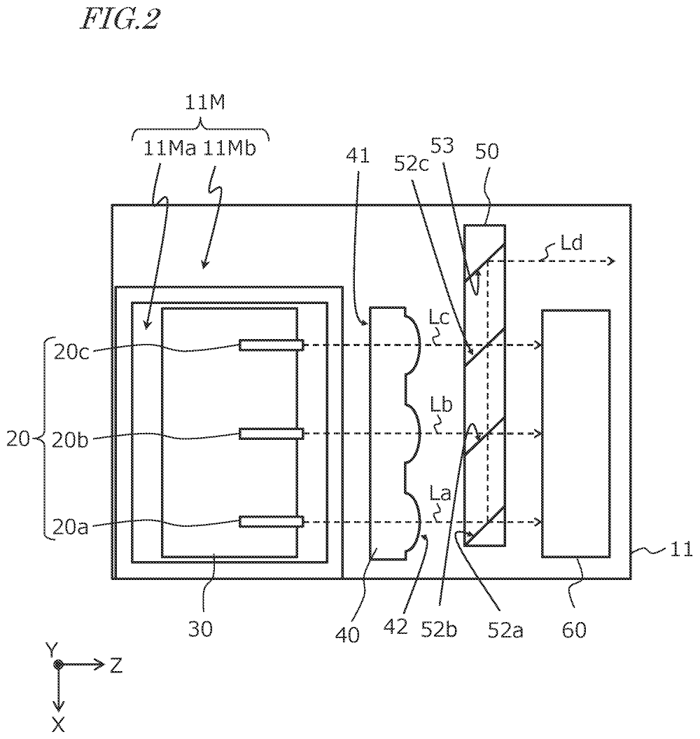

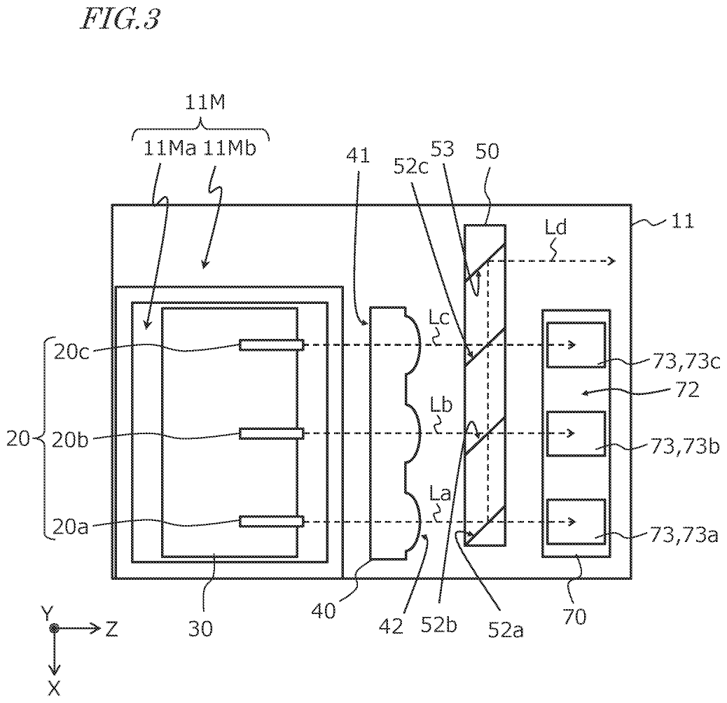

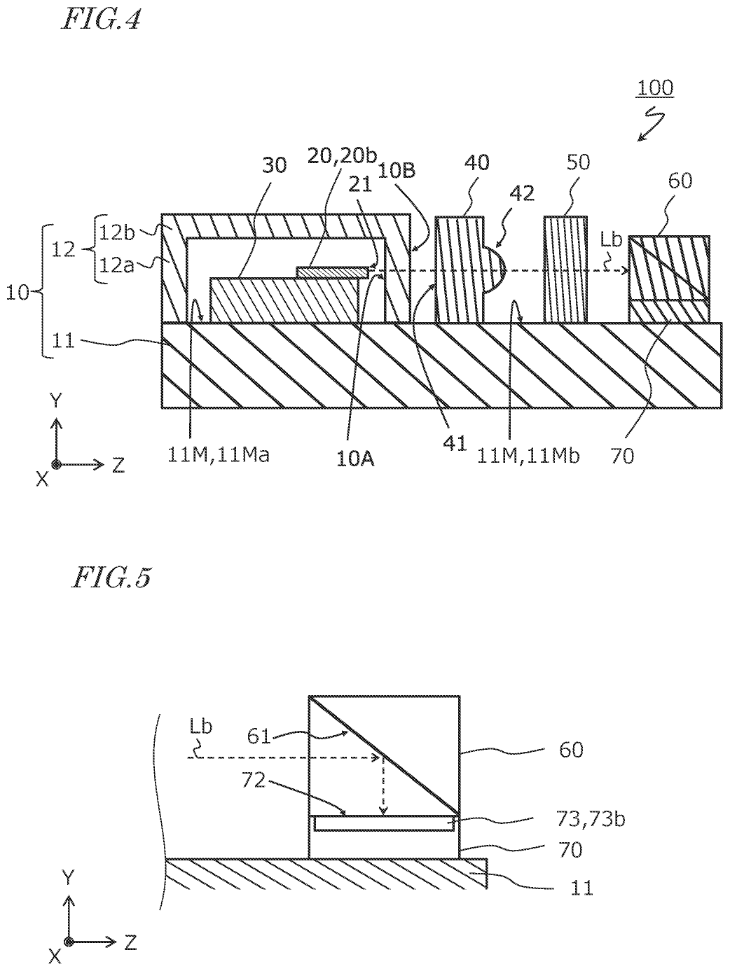

FIG. 1 is a top view of a light emitting device 100 according to the first embodiment. FIG. 2 is a top view of the light emitting device 100 with a cap 12 thereof removed. FIG. 3 is a top view of the light emitting device 100 of FIG. 2 with a reflection member 60 thereof further removed. FIG. 4 is a cross-sectional view taken along line IV-IV of FIG. 1. FIG. 5 is a partially enlarged view of the cross-sectional view of FIG. 4 including the reflection member 60 and a photodetector 70. In FIGS. 2 to 5, light beams emitted from light-emitting elements 20 that travel on respective optical axes are indicated by a dashed line. In FIG. 5, for the sake of clarity, the reflection member 60 and the photodetector 70 are depicted with no hatching.

In the drawings, for reference, an X axis, Y axis, and Z axis, which are orthogonal to each other, are illustrated. The direction indicated by the arrow of the X axis is referred to as a “+X direction,” and the direction opposite to that direction is referred to as a “−X direction.” When it is not necessary to distinguish the +X direction from the −X direction, the +X direction and the −X direction are simply referred to as an “X direction.” The same is true for +Y, −Y, +Z, and −Z directions.

The light emitting device 100 of the first embodiment includes a plurality of component elements including a package 10, one or more light-emitting elements 20, one or more submounts 30, one or more lens members 40, one or more optical members 50, one or more reflection members 60, and one or more photodetectors 70.

In the illustrated example of the light emitting device 100, three light-emitting elements 20 and a submount 30 are provided in a space inside the package 10, and a lens member 40, an optical member 50, a reflection member 60, and a photodetector 70 are provided in a space outside the package 10. Light beams emitted from the three light-emitting elements 20 are emitted out laterally through a light emission surface 10B of the cap 12 before being collimated by the lens member 40. The collimated light beams are combined under the optical control of the optical member 50, and the combined light beam is emitted from the light emitting device 100.

The light emitting device 100, may have a size of, for example, about 8 mm in the X direction, a size of, for example, about 10 mm in the Z direction, and a height of, for example, about 4 mm in the Y direction.

Firstly, each component element will be described.

(Package 10)

The package 10 has a substrate 11 having a mount surface 11M, and a cap 12 joined to the substrate 11. The cap 12 is joined to the mount surface 11M of the substrate 11. Other component elements are further provided on the mount surface 11M. As illustrated in other embodiments described below, the cap 12 may be joined to a different surface that is located on the same side as that of the mount surface 11M. The package 10 forms a closed space that can accommodate other component elements. The closed space may be sealed in a vacuum or hermetic state. An outer shape of the cap 12 is encompassed by an outer shape of the substrate 11 in a top view.

In the illustrated example, the substrate 11 is in the shape of a flat plate. The substrate 11 has an upper surface and a lower surface opposite the upper surface. The upper surface may serve as the mount surface 11M. The upper surface of the substrate 11 has a first mount region 11Ma and a second mount region 11Mb. The mount surface 11M, which is a flat surface, includes the first mount region 11Ma and the second mount region 11Mb. The substrate 11 may be formed of a ceramic as the main material. Examples of the ceramic include aluminum nitride, silicon nitride, aluminum oxide, and silicon carbide.

The cap 12 includes a side wall 12a and an upper portion 12b. The cap 12 has a recessed-shape part formed by the side wall 12a and the upper portion 12b. An outer shape of the cap 12 is rectangular in a top view. The outer shape of the cap 12 may not be rectangular in a top view, and may, for example, be polygonal other than quadrangular, or circular. The substrate 11, the side wall 12a, and the upper portion 12b form a closed space of the package 10.

The first mount region 11Ma of the substrate 11 is surrounded by the side wall 12a in a top view. The side wall 12a extends upward from the mount surface 11M. The second mount region 11Mb is not surrounded by the side wall 12a in a top view. The upper portion 12b is located above the mount surface 11M, and is connected to the side wall 12a. The upper portion 12b has a lower surface opposite the upper surface of the substrate 11. As illustrated in other embodiments described below, the second mount region 11Mb may be located below (at a lower position) the first mount region 11Ma.

The cap 12 is formed of, for example, a light-transmitting material such as glass, plastic, quartz, or sapphire. For example, the cap 12 may be produced using a processing technique such as etching. The cap 12 may be produced by forming the upper portion 12b and the side wall 12a separately using different materials as the main material, and then joining the upper portion 12b and the side wall 12a together. For example, the main material for the upper portion 12b is a non-light-transmitting material such as monocrystalline or polycrystalline silicon, and the main material for the side wall 12a is a light-transmitting material such as glass.

The package 10 is not limited to the structure in which the cap 12 having the side wall 12a and the upper portion 12b is joined to the substrate 11. For example, the package 10 may be formed by a structure in which a cap having the upper portion 12b is joined to a substrate having the side wall 12a. Thus, the package 10 has a lower portion having the first mount region 11Ma, the side wall 12a surrounding the first mount region 11Ma, and the upper portion 12b opposite the lower portion, to form a closed space including the first mount region 11Ma.

The side wall 12a has a light incident surface 10A and the light emission surface 10B, which have light-transmitting properties. Of one or more outer lateral surfaces of the side wall 12a, at least one outer lateral surface serves as the light emission surface 10B. As used herein, a statement that a certain region has “light-transmitting properties” means that the transmittance of the region with respect to a main light beam entering the region is at least 80%. In addition to the light incident surface 10A and the light emission surface 10B, other surfaces (an inner lateral surface or an outer lateral surface) of the side wall 12a may have light-transmitting properties. In the illustrated example, the package 10 has four outer lateral surfaces corresponding to the rectangular outer shape of the cap 12. The light emission surface 10B, and an outer lateral surface opposite the light emission surface 10B, have light-transmitting properties, and the other two outer lateral surfaces do not have light-transmitting properties.

At least one interconnection pattern used for electrical connection between component elements and a power supply is provided on the substrate 11. The interconnection pattern may be formed by a plurality of metal films patterned on a surface of the substrate 11, and vias connecting these metal films together.

Light-Emitting Element 20

The light-emitting element 20 emits light from a light emission surface 21. An example of the light-emitting element 20 is a semiconductor laser element. The light-emitting element 20 may be an edge-emitting semiconductor laser element having a rectangular outer shape in a top view, as in the illustrated example. In the case in which the light-emitting element 20 is an edge-emitting semiconductor laser element, a lateral surface including one of the two shorter sides of the rectangle in a top view serves as a light emission edge surface, which is the light emission surface 21. It should be noted that the light-emitting element 20 is not limited to an edge-emitting semiconductor laser element, and may be a surface-emitting semiconductor laser element or a light emitting diode (LED). The light-emitting element 20 may be a single-emitter having a single emitter, or a multi-emitter having two or more emitters.

In the case in which the light-emitting element 20 is a semiconductor laser element, light (laser light) emitted from the semiconductor laser element forms an elliptical far-field pattern (hereinafter referred to as an “FFP”) on a plane parallel to the light emission surface 21. The FFP refers to the shape or intensity distribution of emitted light at a location away from the light emission surface. A light beam that passes through the center of the ellipse of the FFP is called the optical axis of laser light. The light beam traveling on the optical axis has a peak intensity in the light intensity distribution of the FFP.

The light-emitting element 20 may be a semiconductor laser element that emits blue light. Alternatively, the light-emitting element 20 may be a semiconductor laser element that emits green light. Alternatively, the light-emitting element 20 may be a semiconductor laser element that emits red light. Alternatively, the light-emitting element 20 may be a semiconductor laser element that emits infrared light. Alternatively, the light-emitting element 20 may be a semiconductor laser element that emits light having a wavelength other than those of the above light beams.

As used herein, blue light refers to light whose peak emission wavelength is in the range of 420 nm to 494 nm. Green light refers to light whose peak emission wavelength is in the range of 495 nm to 570 nm. Red light refers to light whose peak emission wavelength is in the range of 605 nm to 750 nm. Infrared light refers to light whose peak emission wavelength is in the range of 780 nm to 2000 nm.

An example of the semiconductor laser element emitting blue light or the semiconductor laser element emitting green light is a semiconductor laser element containing a nitride semiconductor. Examples of the nitride semiconductor include GaN, InGaN, and AlGaN. The semiconductor laser element emitting red light or the semiconductor laser element emitting infrared light may contain an InAlGaP, GaInP, GaAs, or AlGaAs semiconductor.

Submount 30

The submount 30, which is in the shape of a rectangular cuboid, has two mount surfaces. The shape of the submount 30 is not limited to a rectangular cuboid. One of the mount surfaces is located on the opposite side from the other. The upper surface and lower surface of the submount 30 may serve as the two mount surfaces. The submount 30 may be formed of, for example, silicon nitride, aluminum nitride, or silicon carbide. The upper surface of the submount 30 has a plurality of interconnect regions that are electrically coupled to other component elements.

Lens Member 40

The lens member 40 has one or more lens surfaces. The lens surface is, for example, shaped so as to collimate incident light and emit the resultant light. The lens member 40 has one or more incident surfaces 41 and one or more emission surfaces 42. The lens surface(s) may be an incident surface 41 and/or an emission surface 42. In the illustrated example, the lens member 40 has an incident surface 41 and a plurality of emission surfaces 42. The incident surface 41 is a plane, and the emission surfaces 42 are each a lens surface.

The plurality of lens surfaces of the lens member 40 are aligned in a direction. In the illustrated example of the lens member 40, the plurality of lens surfaces are aligned in the X direction. An example of the lens surface is a spheric lens or aspheric lens. The lens member 40 may be formed of a material having light-transmitting properties such as glass, plastic, or resin.

Optical Member 50

The optical member 50 coaxially combines a plurality of incident light beams, and emits the resultant combined light beam. The optical member 50 has one or more optical surfaces. The optical member 50 has a light reflection surface 53. The optical surface has a light control region. The light control region controls transmission or reflection of one or more incident light beams. The optical member 50 may, for example, be a dichroic mirror. The light control region may be formed of a dielectric multilayer film having predetermined wavelength selectivity. The dielectric multilayer film may be formed of, for example, Ta₂O₅/SiO₂, TiO₂/SiO₂, or Nb₂O₅/SiO₂.

The optical member 50 has a plurality of optical surfaces. The optical member 50 is not limited to such a structure. As illustrated in other embodiments described below, a plurality of optical members 50, each of which has an optical surface, may be separated from each other, and may be configured to coaxially combine a plurality of incident light beams, and emit the resultant combined light beam. In other words, one or more optical members 50 coaxially combines a plurality of incident light beams, and emits the resultant combined light beam.

Reflection Member 60

The reflection member 60 has a light reflection surface 61 illustrated in FIG. 5. The reflection member 60 has a structure in which two optical prisms (transparent triangular prisms) are joined together with a metal thin film interposed therebetween. The reflection member 60 is in the shape of a rectangular cuboid as a whole. The reflection member 60 is not limited to the illustrated structure as long as the reflection member 60 has the light reflection surface 61. The light reflection surface 61 is inclined with respect to a lower surface of the reflection member 60. The light reflection surface 61 is a plane that is inclined with respect to the lower surface of the reflection member 60 at an angle of, for example, 40 degrees to 50 degrees.

Photodetector 70

The photodetector 70 has a lower surface, and a light receiving surface 72 located on the opposite side from the lower surface. The lower surface may serve as a mount surface that is joined to other component elements. An outer shape of the photodetector 70 is in the shape of a rectangular cuboid. The outer shape may be different from a rectangular cuboid. A length in the X direction of the light receiving surface 72 is greater than a length in the Z direction of the light receiving surface 72. An outer shape of the light receiving surface 72 is in the shape of a rectangle. The outer shape of the light receiving surface 72 may not be rectangular. The light receiving surface 72 may have one or more light-receiving regions 73. An example of the photodetector 70 is a photoelectric conversion element (photodiode) that outputs an electrical signal corresponding to the intensity or light amount of incident light.

In the illustrated example, the light receiving surface 72 of the photodetector 70 has a plurality of light-receiving regions 73. The plurality of light-receiving regions 73 are aligned in a direction. The light-receiving regions 73 receive light beams having different wavelengths. As illustrated in other embodiments described below, a plurality of photodetectors 70 having respective light-receiving regions 73 may receive light beams having different wavelengths. In other words, one or more photodetectors 70 can receive light beams having different wavelengths. Instead of receiving light beams having different wavelengths, a plurality of light-receiving regions 73 may receive light beams emitted from different light-emitting elements, for example.

Next, the light emitting device of the first embodiment will be described.

Light Emitting Device 100

In the light emitting device 100, one or more light-emitting elements 20 are provided on the mount surface 11M. The one or more light-emitting elements 20 are located in the first mount region 11Ma. The one or more light-emitting elements 20 are joined to the upper surface of the submount 30. The submount 30 is joined to the substrate 11. The one or more light-emitting elements 20 may be directly joined to the substrate 11 without the submount 30 interposed.

The one or more light-emitting elements 20 are located in the closed space of the package 10. By hermetically sealing the package 10 under a predetermined atmosphere, a deterioration in quality due to dust can be reduced. Light emitted from the one or more light-emitting elements 20 travels laterally to enter the light incident surface 10A of the side wall 12a. The light entering the light incident surface 10A is passed through the light emission surface 10B, and is emitted laterally.

In the illustrated example of the light emitting device 100, the plurality of light-emitting elements 20 are aligned in a direction in a top view. The plurality of light-emitting elements 20 are aligned in the X direction. The plurality of light-emitting elements 20 are provided on the single submount 30. A plurality of submounts 30 may be provided for the plurality of light-emitting elements 20 such that only one light-emitting element 20 is provided on each submount 30. Each light-emitting element 20 emits light traveling from the emission edge surface in a first direction. A second direction in which the plurality of light-emitting elements 20 are aligned is perpendicular to the first direction in a top view. Light emitted from each light-emitting element 20 is emitted from the light emission surface 10B, and travels in the first direction.

The one or more light-emitting elements 20 may include a first light-emitting element 20a and a second light-emitting element 20b. The one or more light-emitting elements 20 may further include a third light-emitting element 20c. All of the light-emitting elements 20 may be semiconductor laser elements. In the illustrated example of the light emitting device 100, the first light-emitting element 20a, the second light-emitting element 20b, and the third light-emitting element 20c are aligned in the −X direction in the stated order.

The first light-emitting element 20a emits a first light La. The second light-emitting element 20b emits a second light Lb, which has a color different from that of the first light La. The third light-emitting element 20c emits a third light Lc, which has a color different from those of the first light La and the second light Lb. For example, the first light La, the second light Lb, and the third light Lc have different colors and are each selected from red light, green light, and blue light. It should be noted that the second light Lb and the third light Lc may have the same color as that of the first light La. For example, the first light La may be blue light, the second light Lb may be green light, and the third light Lc may be red light.

For example, all of the first light-emitting element 20a, the second light-emitting element 20b, and the third light-emitting element 20c are semiconductor laser elements. The first light La, the second light Lb, and the third light Lc are blue light having a peak emission wavelength of 460 nm±10 nm, green light having a peak emission wavelength of 526 nm±11 nm, and red light having a peak emission wavelength of 639 nm±10 nm, respectively. Therefore, the color gamut defined by International Standards BT.2020 can be generally covered, and the semiconductor laser elements can provide light suitable for display applications.

The first light-emitting element 20a, the second light-emitting element 20b, and the third light-emitting element 20c are aligned and spaced in the X direction. in a top view, the light emission points of the plurality of light-emitting elements 20 are aligned in a straight line parallel to the X direction. The interval between the light emission points of two adjacent light-emitting elements 20 may be regulated within the range of, for example, 200 μm to 2000 μm.

The optical axis direction of the second light Lb emitted from the second light-emitting element 20b is parallel to the optical axis direction of the first light La emitted from the first light-emitting element 20a. The optical axis direction of the third light Lc emitted from the third light-emitting element 20c is parallel to the optical axis direction of the first light La emitted from the first light-emitting element 20a. As used herein, the term “parallel” is intended to encompass some deviations from absolute parallelism that are in the range of about ±2 degrees. The optical axis direction of light is perpendicular to the emission edge surface of the light-emitting element 20. The optical axis of light is parallel to the first direction.

The one or more lens members 40 are located in the second mount region 11Mb. The one or more optical members 50 are located in the second mount region 11Mb. The one or more reflection members 60 and the one or more photodetectors 70 are located in the second mount region 11Mb. All upper ends of the lens member(s) 40, the optical member(s) 50, and the reflection member(s) 60 are located above an upper end of the one or more light-emitting elements 20. Constituent elements located above the light-emitting element 20 in the Y direction are provided outside the closed space, whereby the height of the cap 12 can be reduced, and therefore, the light-emitting element 20 can be protected and the size of the light emitting device 100 can be reduced.

The one or more lens members 40 are spaced away from the light emission surface 10B in the first direction. The one or more optical members 50 are spaced away from the light emission surface 10B in the first direction. The one or more photodetectors 70 are spaced away from the light emission surface 10B in the first direction. The one or more lens members 40 and the one or more photodetectors 70 are located so as not to overlap in a top view. The one or more optical members 50 and the one or more photodetectors 70 are located so as not to overlap in a top view.

The one or more optical members 50 are located further away (in the first direction) from the light emission surface 10B than is the one or more lens members 40. The one or more photodetectors 70 are located further away (in the first direction) from the light emission surface 10B than is the one or more optical members 50. The one or more reflection members 60 are located on the one or more photodetectors 70. When the light-emitting element 20 emits diverging light, the diameter of the light increases with an increase in the optical path length, and therefore, the size of the lens member 40 can be reduced by locating the lens member(s) 40 relatively close to the light emission surface 10B. This contributes to a reduction in size of the light emitting device 100.

Light that is emitted from the one or more light-emitting elements 20 and then emitted from the light emission surface 10B enters the incident surface 41 of the one or more lens members 40. The light entering the incident surface 41 is diverging light. The one or more lens members 40 collimate the light entering the incident surface 41, and emit the resultant collimated light. The lens surface(s) of the one or more lens members 40 are provided so as to collimate light emitted from the one or more light-emitting elements 20. The optical axis of the lens surface is coincident or coaxial with the optical axis of light that is emitted from the light emission surface 10B, and then enters the lens surface. As used herein, the term “coincident” is intended to encompass some deviations from absolute coincidence of two optical axes due to manufacturing error.

In the illustrated example of the light emitting device 100, the first light La and the second light Lb, which are diverging light, enter the one or more lens members 40. The one or more lens members 40 collimate the first light La and the second light Lb entering thereinto, and emit the collimated first light La and second light Lb. In addition, the third light Lc, which is diverging light, enters the one or more lens members 40. The one or more lens members 40 collimate the third light Lc entering thereinto, and emit the collimated third light Lc. The lens member 40 has an incident surface 41, and three emission surfaces 42 corresponding to three light-emitting elements 20. In the light emitting device 100, a single lens member 40 collimates light beams from three light-emitting elements 20.

The one or more optical members 50 combine the first light La and the second light Lb. Furthermore, the one or more optical members 50 combines the first light La, the second light Lb, and the third light Lc. The one or more optical members 50 combine the resultant collimated light beams. The one or more optical members 50 emit a combined light beam Ld.

The one or more optical members 50 have a first optical surface 52a that the first light La enters in the first direction, and a second optical surface 52b that the second light Lb enters in the first direction. The one or more optical members 50 also have the light reflection surface 53 that combines the first light La and the second light Lb, and emits the resultant light in the first direction. The one or more optical members 50 further have a third optical surface 52c that the third light Lc enters in the first direction. Furthermore, the light reflection surface 53 combines the first light La, the second light Lb, and the third light Lc, and emits the resultant light in the first direction. Each of the optical surfaces 52a, 52b, and 52c transmits a portion of light entering in the first direction, and reflects the remainder. A portion of light entering in the first direction is reflected, travels toward the light reflection surface 53, and is combined with the other light beams.

Each of the light beams La, Lb, and Lc entering in the first direction that have passed through the respective optical surfaces 52a, 52b, and 52c are received by the photodetector 70. The one or more photodetectors 70 receives the first light La and the second light Lb. The at least one photodetector 70 also receives the third light Lc.

As illustrated in FIG. 5, in the light emitting device 100, the one or more photodetectors 70 receive the light beams La, Lb, and Lc reflected by the one or more reflection members 60, which are located above the one or more photodetectors 70. The one or more reflection members 60 have one or more light reflection surfaces 61 that reflect light transmitted through the one or more optical members 50 downward.

The one or more photodetectors 70 have a first light-receiving region 73a that receives the first light La, and a second light-receiving region 73b that receives the second light Lb. The one or more photodetectors 70 further have a third light-receiving region 73c that receives the third light Lc. In a top view, the light-receiving regions 73 are inside a periphery of the one or more reflection members 60.

The first light-receiving region 73a, the second light-receiving region 73b, and the third light-receiving region 73c are provided in the light receiving surface 72. The first light-receiving region 73a, the second light-receiving region 73b, and the third light-receiving region 73c are aligned in a direction that is perpendicular to the optical axis direction of light emitted from each light-emitting element 20 and parallel to the mount surface 11M, i.e., the X direction, in a top view.

In the light emitting device 100 of the first embodiment, a combined light beam can be generated by coaxially combining a plurality of light beams emitted from the plurality of light-emitting elements 20, and the intensities of light beams emitted from the plurality of light-emitting elements 20 can be individually monitored by the photodetector 70. The photodetector 70 is mounted on the substrate 11 with the light-receiving region 73 of the upper surface facing upward, and therefore, the lower surface of the photodetector 70 can be directly used for electrical connection to the substrate 11. Furthermore, the lens member 40 is located close to the light emission surface 10B, which may particularly contribute to a reduction in size of the light emitting device 100 in the Y direction.

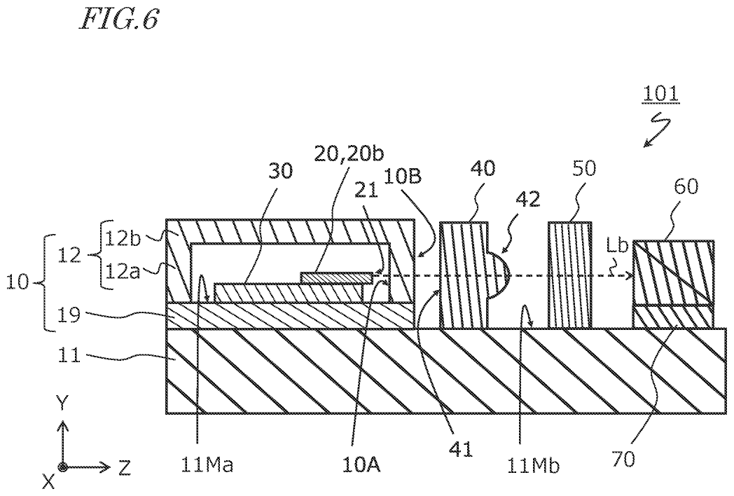

FIG. 6 is a cross-sectional view of a light emitting device 101 further including a substrate 19 that is different from the substrate 11. The cross-sectional view of FIG. 6 corresponds to the cross-sectional view of the light emitting device 100 of FIG. 4. In the package 10 of the light emitting device 101, a space that is formed by joining the cap 12 to the substrate 19 and in which the light-emitting element 20 is provided, is sealed. The package 10 may be provided on the substrate 11. The first mount region 11Ma is provided in the upper surface of the substrate 19, and the second mount region 11Mb is provided in the upper surface of the substrate 11. In the case of the light emitting device 101, the package 10 in which the light-emitting element 20 is mounted can be manufactured separately from the substrate 11, likely leading to an increase in yield.

Variation

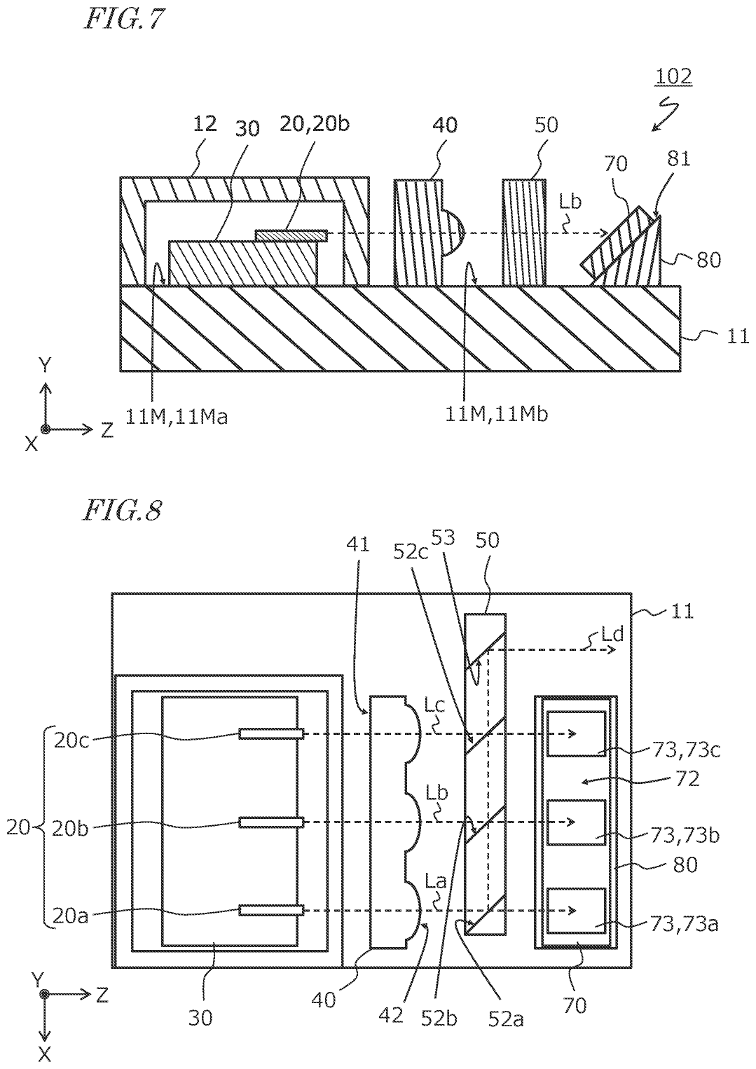

A variation of the light emitting device 100 of the first embodiment will be described with reference to FIGS. 7 and 8.

FIG. 7 is a cross-sectional view of a light emitting device 102 that is a variation of the light emitting device 100. The cross-sectional view of FIG. 7 corresponds to the cross-sectional view of the light emitting device 100 of FIG. 4. FIG. 8 is a top view of the light emitting device 102 with the cap 12 removed.

The light emitting device 102 is different from the light emitting device 100 in that the light emitting device 102 includes at least one support member 80, and the photodetector 70 is provided on an inclined support surface of the support member 80. The difference will be mainly described below without describing similarities.

Support Member 80

The support member 80 has a lower surface and a support surface 81 that is inclined with respect to the lower surface. The support surface 81 is inclined with respect to the lower surface at an angle that falls within a certain range. The angle of inclination is in the range of, for example, 10 degrees to 80 degrees, preferably 40 degrees to 50 degrees. In the illustrated example of the light emitting device 102, the support surface 81 is inclined with respect to the lower surface at an angle of 45 degrees.

The support member 80 may be formed of, for example, ceramic, glass, or metal. For example, ceramics such as aluminum nitride, glasses such as quartz and borosilicate glass, and metals such as aluminum may be used. The support member 80 may also be formed of, for example, silicon.

In the light emitting device 102, one or more support members 80 are disposed in the second mount region 11Mb. The photodetector 70 is disposed on the support surface 81 that is an inclined surface of the support member 80. An upper end of the support surface 81 is located above an upper end of the light-emitting element 20. The light receiving surface 72 of the photodetector 70 supported by the support surface 81 is inclined with respect to the optical axis direction of light emitted from each light-emitting element 20. The light receiving surface 72 is inclined with respect to the optical axis direction at an angle that falls within the range of, for example, 40 degrees to 50 degrees.

In the one or more photodetectors 70, the plurality of light-receiving regions 73 are aligned in the X direction. The light beams La, Lb, and Lc travel in the first direction, and enter the respective light-receiving regions 73 at an angle other than a right angle. At the light receiving surface 72, a portion of light may be reflected without being received. Even in such a case, as light enters the light receiving surface 72 at an angle other than a right angle, and therefore, light is reflected by the light receiving surface 72, so that light returning to the light-emitting element 20 can be reduced.

### Second Embodiment

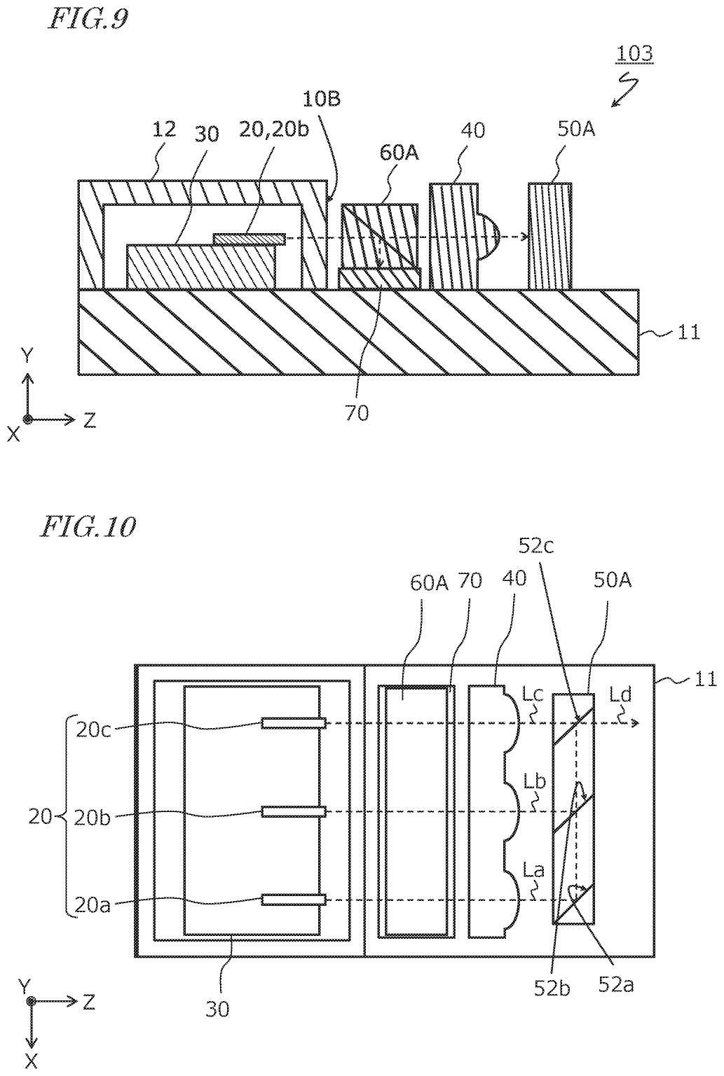

A light emitting device according to a second embodiment of the present disclosure will be described with reference to FIGS. 9 to 11.

The light emitting device of the second embodiment is different from the light emitting device of the first embodiment in that the photodetector 70 is located between the light emission surface 10B and the lens member 40. The light emitting device of the second embodiment is also different from the light emitting device of the first embodiment in that a reflection member 60A is provided between the light emission surface 10B and the lens member 40. The light emitting device of the second embodiment is also different from the light emitting device of the first embodiment in that the former does not include the light reflection surface 53, and includes an optical member 50A in which light is controlled in the light control region of the optical surface in a manner different from that of the optical member 50. The difference will be mainly described below without describing similarities.

FIG. 9 is a cross-sectional view of a light emitting device 103 according to the second embodiment. The cross-sectional view of FIG. 9 corresponds to the cross-sectional view of the light emitting device 100 of FIG. 4. FIG. 10 is a top view of the light emitting device 103 with the cap 12 removed. FIG. 11 is a partially enlarged view of the cross-sectional view of FIG. 9 including the reflection member 60A and the photodetector 70.

Optical Member 50A

The optical member 50A is the same as the optical member 50, except that the optical member 50A does not have the light reflection surface 53, and light emitted from the light-emitting element 20 is controlled in the light control region in a manner different from that of the optical member 50.

Reflection Member 60A

The reflection member 60A has a structure in which the light reflection surface 61 of the reflection member 60 is replaced by a partial reflection surface 63. The partial reflection surface 63 reflects a portion of incident light, and transmits the remainder. The partial reflection surface 63 may serve as a beam splitter. Light entering the partial reflection surface 63 is split into two light beams that travel in different directions. The two split light beams each include light having the same wavelength. The reflection member 60A splits the same wavelength component of incident light into two at a predetermined ratio. For example, one of the two split light beams obtained by the reflection member 60A may be used as a main light beam (hereinafter referred to as “main light”), and the other may be used as a light beam for monitoring for controlling the main light (hereinafter referred to as “monitoring light”).

When incident light is split into main light and monitoring light, the intensity of the monitoring light is smaller than the intensity of the main light. For example, the partial reflection surface 63 transmits 80% to 99.5% of incident light, and reflects 0.5% to 20.0% of incident light.

In the light emitting device 103, the one or more photodetectors 70 are located closer to the light emission surface 10B than is the one or more lens members 40. The reflection member 60A and the photodetector 70 are located between the cap 12 and the lens member 40. The one or more reflection members 60A are located above the light receiving surface 72 of the one or more photodetectors 70. A portion of light that is emitted from each light-emitting element 20 and enters the reflection member 60A is transmitted through the partial reflection surface 63 to enter the lens member 40, and the remainder is reflected by the partial reflection surface 63 to reach the light receiving surface 72 of the photodetector 70. For example, light transmitted through the partial reflection surface 63 can be used as the main light.

Light beams La, Lb, and Lc transmitted through the one or more reflection members 60A are combined and emitted by the one or more optical members 50A. The combined light beam Ld travels in the first direction. Light entering the optical surface of the one or more optical members 50A has been collimated by the one or more lens members 40. The one or more lens members 40 are located between the one or more photodetectors 70 and the one or more optical members 50A in a top view.

The first optical surface 52a of the one or more optical members 50A reflects the first light La entering in the first direction. In the light emitting device 103, it is not necessary to cause a portion of the first light La entering in the first direction to transmit through the first optical surface 52a so that the portion of the first light La reaches the photodetector 70. Therefore, the first optical surface 52a only reflects the first light La entering in the first direction. One of the optical surfaces through which the combined light beam is emitted in the first direction transmits light entering in the first direction. For example, if only the first light La and the second light Lb exist, the second optical surface 52b transmits the second light Lb entering in the first direction. In addition, if, for example, as illustrated, the first light La, the second light Lb, and the third light Lc are combined, the third optical surface 52c transmits the third light Lc entering in the first direction.

In the light emitting device 103 of the second embodiment, the intensity of light emitted from each light-emitting element 20 can be individually monitored using the photodetector 70. In addition, by changing the location of the photodetector 70, light beams can be combined by the optical member 50A without the light reflection surface 53, and therefore, a size in the X direction can be reduced, which contributes to a reduction in size of the light emitting device.

### Third Embodiment

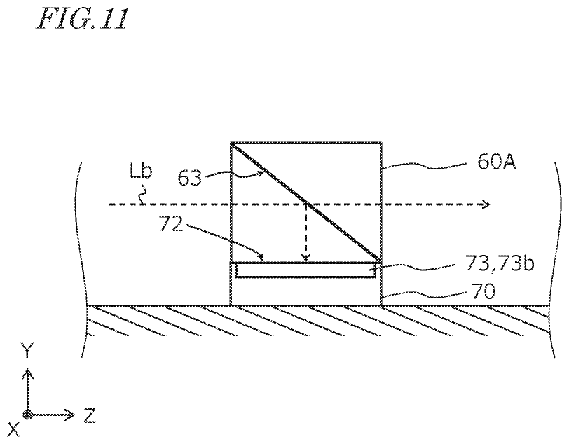

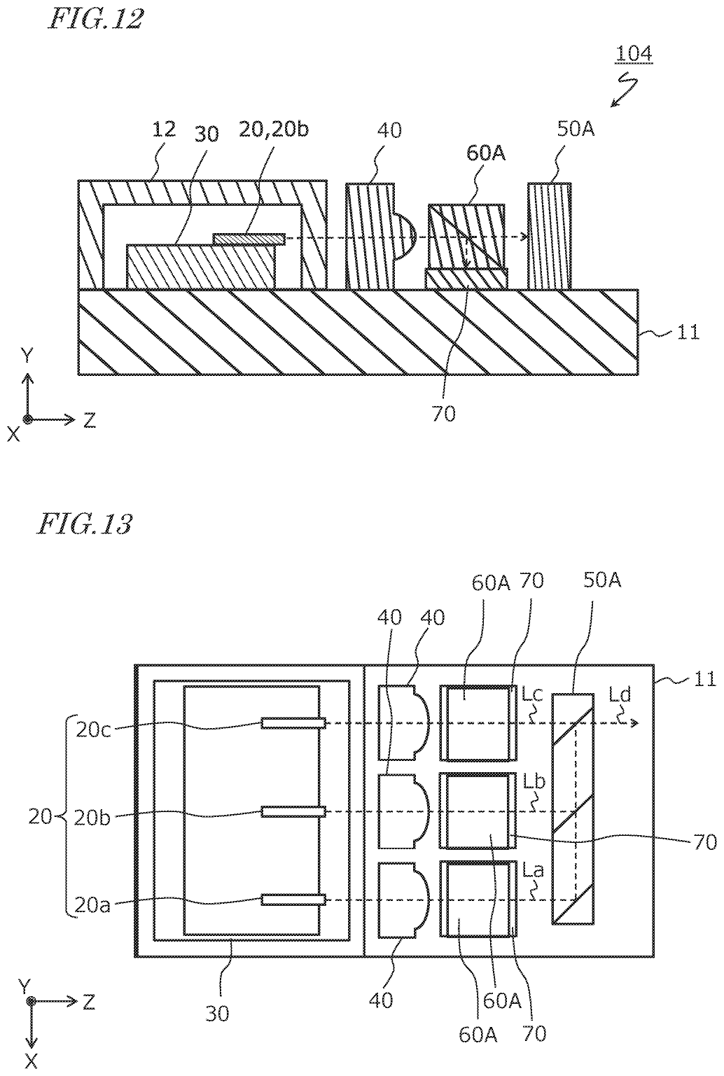

A light emitting device according to a third embodiment of the present disclosure will be described with reference to FIGS. 12 and 13.

The light emitting device of the third embodiment is different from the light emitting device of the second embodiment in that the photodetector 70 is located between the lens member 40 and the optical member 50A. The difference will be mainly described below without describing similarities.

FIG. 12 is a cross-sectional view of a light emitting device 104 according to the third embodiment. The cross-sectional view of FIG. 12 corresponds to the cross-sectional view of the light emitting device 100 of FIG. 4. FIG. 13 is a top view of the light emitting device 104 with the cap 12 removed.

In the light emitting device 104, the one or more photodetectors 70 are located further away from the light emission surface 10B than is the one or more lens members 40. The one or more photodetector 70 are also located closer to the light emission surface 10B than is the one or more optical member 50A. The one or more lens members 40 are located close to the light emission surface 10B compared to the light emitting device of the second embodiment, and therefore, the magnitude of the diameter of the collimated light can be reduced. As a result, a size in the Y direction can be reduced, which contributes to a reduction in size of the light emitting device.

In the illustrated example of the light emitting device 104, a lens member 40 is provided for each light-emitting element 20. The plurality of lens members 40 are aligned in the X direction. A photodetector 70 is provided for each light-emitting element 20. The plurality of photodetectors 70 are aligned in the X direction. A reflection member 60A is provided for each photodetector 70. Thus, the lens members 40 are individually provided for the respective light-emitting elements 20, and therefore, the locations of the lens members 40 can be individually adjusted, resulting in an improvement in accuracy of collimation.

Light beams La, Lb, and Lc passed through the one or more reflection members 60A are combined and emitted by the one or more optical members 50A. The combined light beam Ld travels in the first direction. Light entering the optical surface of the one or more optical members 50A has been collimated by the one or more lens members 40. The one or more lens members 40 are located between the one or more photodetectors 70 and the one or more optical members 50A in a top view.

### Fourth Embodiment

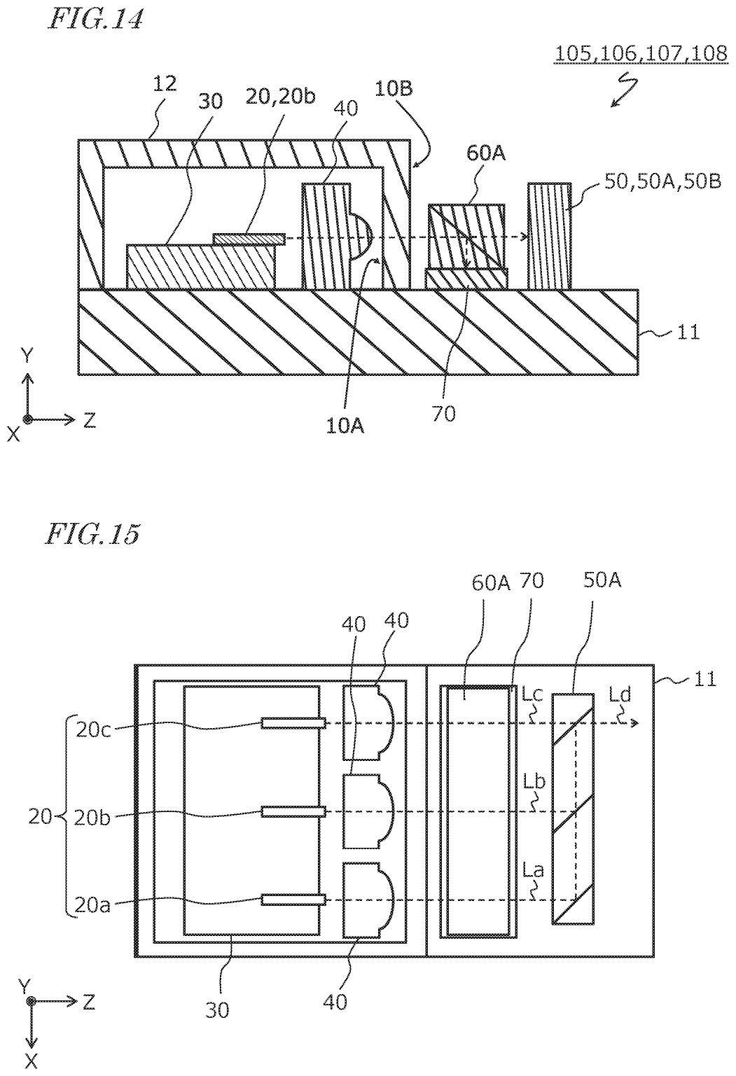

A light emitting device according to a fourth embodiment of the present disclosure will be described with reference to FIGS. 14 and 15.

The light emitting device of the fourth embodiment is different from the light emitting devices of the above embodiments in that the lens member 40 is located in the closed space of the package 10. The difference will be mainly described below without describing similarities.

FIG. 14 is a cross-sectional view of a light emitting device 105 according to the fourth embodiment. The cross-sectional view of FIG. 14 corresponds to the cross-sectional view of the light emitting device 100 of FIG. 4. FIG. 15 is a top view of the light emitting device 105 with the cap 12 removed.

In the light emitting device 105, the one or more lens members 40 are provided in the closed space of the package 10. Diverging light emitted from the one or more light-emitting elements 20 travels in the first direction, enters the one or more lens members 40, and is emitted in the form of collimated light. The collimated light enters the light incident surface 10A of the package 10, and is emitted from the light emission surface 10B. As the cap 12 is not interposed between the light-emitting element 20 and the lens member 40, the lens member 40 can be located closer to the light-emitting element 20, and therefore, the magnitude of the diameter of the collimated light can be reduced. As a result, the magnitude of the diameter of combined light emitted from the light emitting device can be reduced.

### Fifth Embodiment

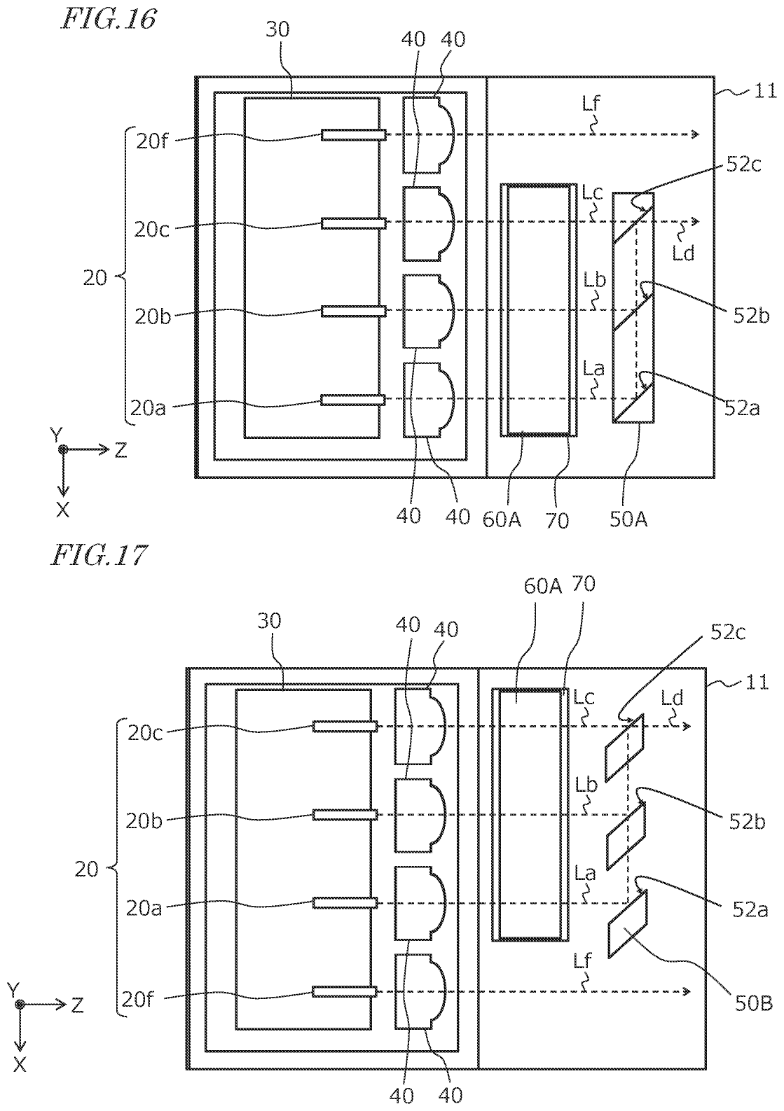

A light emitting device according to a fifth embodiment of the present disclosure will be described with reference to FIGS. 14 and 16.

The light emitting device of the fifth embodiment is different from the light emitting devices of the above embodiments in that the former includes a fourth light-emitting element 20f. The difference will be mainly described below without describing similarities.

FIG. 14 is a cross-sectional view of a light emitting device 106 according to the fifth embodiment. The cross-sectional view of FIG. 14 corresponds to the cross-sectional view of the light emitting device 100 of FIG. 4. FIG. 16 is a top view of the light emitting device 106 with the cap 12 removed.

The light emitting device 106 includes the fourth light-emitting element 20f. The fourth light-emitting element 20f emits a fourth light beam, which is infrared light. The light emitting device 106 includes a plurality of light-emitting elements 20 including the fourth light-emitting element 20f. The plurality of light-emitting elements 20 are aligned in the X direction. In the light emitting device 106, the fourth light beam Lf is not combined with any of the other light beams La, Lb, and Lc. The at least one optical member 50A is not located on the optical path of the fourth light beam Lf.

In the illustrated example of the light emitting device 106, the first light-emitting element 20a, the second light-emitting element 20b, the third light-emitting element 20c, and the fourth light-emitting element 20f are aligned in the X direction in the stated order. In the third optical surface 52c, the first light La, the second light Lb, and the third light Lc are combined and emitted in the first direction. Both of the combined light beam Ld and the fourth light beam Lf travel in the first direction.

The combined light beam Ld and the fourth light beam Lf, which are located close to each other, travel in parallel. A distance between a first location where the first light La, the second light Lb, and the third light Lc are combined, and a second location where a virtual line passing through the first location and parallel to the X direction in a top view intersects with the fourth light beam, is shorter than a distance between the first light-emitting element 20a and the third light-emitting element 20c. In the light emitting device 106, combined RGB light and infrared light are emitted with the two light beams separated from each other by a short distance. This arrangement is useful in the case in which it is preferable that the two light beams be located close to each other.

In the light emitting device 106, the one or more photodetectors 70 do not receive the fourth light beam Lf. The at least one photodetector 70 is not located on the optical path of the fourth light beam Lf in a top view. In the case in which the first light La, the second light Lb, and the third light Lc are red (R), green (G), and blue (B) light beams, respectively, and are used in a display, while the fourth light beam Lf is used in detection of a location or distance, the balance of the R, G, and B light beams may be adjusted to control display colors, while it may not be necessary to adjust the infrared light in such a manner. In such a case, the outputs of the first light La, the second light Lb, and the third light Lc are desired to be detected by the one or more photodetectors 70, and it is not necessary to detect the output of the fourth light beam Lf, and therefore, the configuration of the light emitting device 106 is considered to be efficient. It should be noted that a combination of R, G, and B light beams with infrared light is applicable to in-vehicle headlamps, projection mapping to a moving object, and the like, for example.

### Sixth Embodiment

A light emitting device according to a sixth embodiment of the present disclosure will be described with reference to FIGS. 14 and 17.

The light emitting device of the sixth embodiment is different from the light emitting device of the fifth embodiment in that the fourth light-emitting element 20f of the plurality of light-emitting elements 20 is located at a different position. The difference will be mainly described below without describing similarities.

FIG. 14 is a cross-sectional view of a light emitting device 107 according to the sixth embodiment. The cross-sectional view of FIG. 14 corresponds to the cross-sectional view of the light emitting device 100 of FIG. 4. FIG. 17 is a top view of the light emitting device 107 with the cap 12 removed.

In the illustrated example of the light emitting device 107, the fourth light-emitting element 20f, the first light-emitting element 20a, the second light-emitting element 20b, and the third light-emitting element 20c are aligned in the X direction in the stated order. In the third optical surface 52c, the first light La, the second light Lb, and the third light Lc are combined and emitted in the first direction. Both of the combined light beam Ld and the fourth light beam Lf travel in the first direction.

The combined light Ld and the fourth light beam Lf travel in parallel. A distance between a first location where the first light La, the second light Lb, and the third light Lc are combined, and a second location where a virtual line passing through the first location and parallel to the X direction in a top view intersects with the fourth light beam, is longer than a distance between the first light-emitting element 20a and the third light-emitting element 20c. In the light emitting device 106, combined RGB light and infrared light are emitted with the two light beams separated from each other by a distance close to a distance between two located at opposite ends of the plurality of light-emitting elements 20 aligned and spaced. This arrangement is useful in the case in which it is preferable that the two light beams be separated from each other.

In the illustrated example of the light emitting device 107, an optical member 50B having an optical surface is provided for each light-emitting element 20. The plurality of optical members 50B are aligned in the X direction. Thus, the optical members 50B are individually provided for the respective light-emitting elements 20, and therefore, the locations of the optical members 50B can be individually adjusted, resulting in an improvement in accuracy of coaxial combination of a plurality of light beams.

### Seventh Embodiment

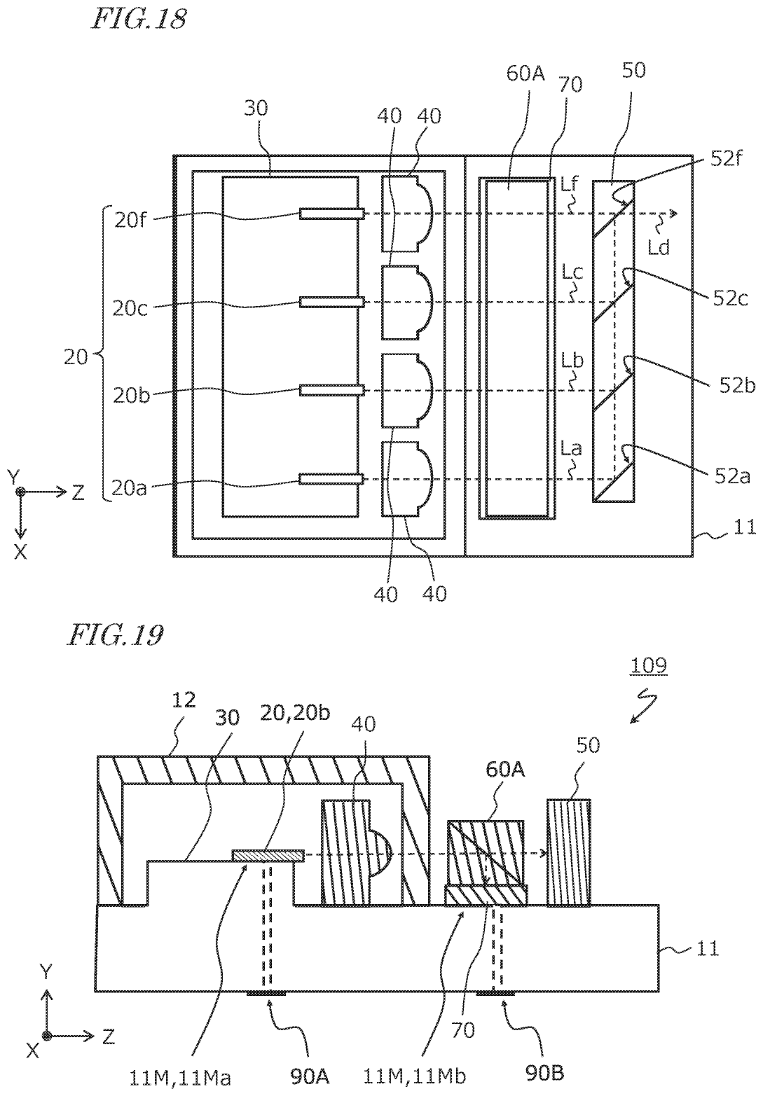

A light emitting device according to a seventh embodiment of the present disclosure will be described with reference to FIGS. 14 and 18.

The light emitting device of the seventh embodiment is different from the light emitting devices of the above embodiments in that light beams emitted from the plurality of light-emitting elements 20 including the fourth light-emitting element 20f are combined. The light emitting device of the seventh embodiment is also different from the light emitting devices of the above embodiments in that the one or more photodetectors 70 receives the fourth light beam Lf. The difference will be mainly described below without describing similarities.

FIG. 14 is a cross-sectional view of a light emitting device 108 according to the seventh embodiment. The cross-sectional view of FIG. 14 corresponds to the cross-sectional view of the light emitting device 100 of FIG. 4. FIG. 18 is a top view of the light emitting device 108 with the cap 12 removed.

The light emitting device 108 includes a fourth light-emitting element 20f. The fourth light-emitting element 20f emits a fourth light beam, which is infrared light. The light emitting device 108 includes a plurality of light-emitting elements 20 including the fourth light-emitting element 20f. The plurality of light-emitting elements 20 are aligned in the X direction. In the light emitting device 108, the fourth light beam Lf is combined with light beams emitted from the other light-emitting elements 20.

In the illustrated example of the light emitting device 108, the first light-emitting element 20a, the second light-emitting element 20b, the third light-emitting element 20c, and the fourth light-emitting element 20f are aligned in the X direction in the stated order. The at least one optical member 50 has a fourth optical surface 52f. The fourth optical surface 52f transmits the fourth light beam Lf that is emitted from the fourth light-emitting element 20f and travels in the first direction, and combines the first light La, the second light Lb, the third light Lc, and the fourth light beam Lf. The combined light beam Ld is emitted from the fourth optical surface 52f in the first direction. In the light emitting device 108, R, G, and B light beams and infrared light can be combined and emitted. Therefore, the light emitting device 108 is useful for the case in which such emitted light is desired.

### Eighth Embodiment

A light emitting device according to an eighth embodiment of the present disclosure will be described with reference to FIG. 19.

The light emitting device of the eighth embodiment is different from the light emitting devices of the above embodiments in the shape of the substrate 11. The difference will be mainly described below without describing similarities.

FIG. 19 is a cross-sectional view of a light emitting device 109 according to the eighth embodiment. The cross-sectional view of FIG. 19 corresponds to the cross-sectional view of the light emitting device 100 of FIG. 4. In FIG. 19, via-interconnects passing in the substrate 11 are indicated with dashed lines.

In the light emitting device 109, the substrate 11 has a first mount surface having a first mount region 11Ma, and a second mount surface having a second mount region 11Mb. The first mount surface is located above the second mount surface. At least one light-emitting element 20 is provided in the first mount region 11Ma, and at least one photodetector 70 is provided in the second mount region 11Mb.

In the substrate 11, an interconnect provided on one surface of the substrate 11, and an interconnect provided on another surface, are electrically coupled through a via-interconnect passing in the substrate 11. In the substrate 11, at least one first interconnect 90A provided on the first mount surface is coupled to a first interconnect 90A provided on another surface through a via-interconnect. At least one second interconnect 90B provided on the second mount surface is coupled to a second interconnect 90B provided on another surface through a via-interconnect. Thus, two mount surfaces having different heights are implemented using the single substrate 11, and therefore, the number of parts such as a submount required for manufacturing a light emitting device can be reduced. In addition, a component element mounted on any mount surface can be electrically coupled to an external part through a via-interconnect, resulting in an improvement in convenience.

Certain embodiments of the present invention have been described above, but the light emitting device of the present invention is not limited to those described in the embodiments. In other words, the present invention can be implemented without being limited to the outer shape or structure of the light emitting device disclosed in the embodiments. The present invention is applicable without necessarily and fully including all of the disclosed parts. For example, some parts of the light emitting device included in the disclosed embodiments may not be recited in the appended claims. Nevertheless, the present invention is intended to embrace all alterations, deletions, deformations, material variations, and the like of such parts, i.e., the flexibility of design, made by a person skilled in the art.

A light emitting device according to an embodiment is applicable to head-mounted displays, projectors, illumination devices, displays, and the like.

What is claimed is:

1. A light emitting device comprising:
a first light-emitting element configured to emit a first light in a first direction;
a second light-emitting element configured to emit a second light in the first direction;
a package comprising a substrate and a cap, wherein the package has a light emission surface through which the first light and second light emitted from the first and second light-emitting elements are passed, and wherein the package forms a closed space in which the first and second light-emitting elements are located;
one or more optical members that are spaced away from the light emission surface in the first direction, and that are configured to combine the first light and second light; and
one or more photodetectors that are spaced away from the light emission surface in the first direction, and that are configured to receive the first light and second light.

2. The light emitting device according to claim 1, further comprising:
one or more support members having an inclined surface, wherein:
the one or more photodetectors are located on the inclined surface of the one or more support members.

3. The light emitting device according to claim 1, further comprising:
one or more reflection members that are located above the one or more photodetectors, and that are configured to reflect the first light and second light downward, wherein:
the one or more photodetectors are configured to receive the first light and second light reflected by the one or more reflection members.

4. The light emitting device according to claim 1, wherein:
the substrate has a mount surface on which the first and second light-emitting elements are located,
the cap has the light emission surface, and
the one or more optical member are located on the mount surface.

5. The light emitting device according to claim 1, wherein:
the one or more optical members and the one or more photodetectors are located so as not to overlap in a top view.

6. The light emitting device according to claim 1, further comprising:
one or more lens members configured to receive the first light as diverging light and the second light as diverging light, and to emit collimated first light and collimated second light, wherein:
the one or more optical member are configured to combine the collimated first light and the collimated second light.

7. The light emitting device according to claim 6, wherein:
the one or more photodetectors are located further away from the light emission surface than are the one or more lens members.

8. The light emitting device according to claim 7, wherein:
the one or more photodetectors are located further away from the light emission surface than are the one or more optical members.

9. The light emitting device according to claim 7, wherein:
the one or more photodetectors are located closer to the light emission surface than are the one or more optical members.

10. The light emitting device according to claim 6, wherein:
the one or more lens members are located in the closed space.

11. The light emitting device according to claim 6, wherein:
the one or more photodetectors are located closer to the light emission surface than are the one or more lens members.

12. The light emitting device according to claim 6, wherein:
the one or more photodetectors have a first light-receiving region configured to receive the first light, and a second light-receiving region configured to receive the second light, the second light-receiving region being spaced away from the first light-receiving region, and
the first and second light-receiving regions are perpendicular to an optical axis direction of light emitted from the first light-emitting element in a top view, are aligned in a direction parallel to the mount surface on which the first light-emitting element is located, and face upward.

13. The light emitting device according to claim 6, further comprising:
a third light-emitting element to emit a third light, wherein:
the one or more optical members are configured to combine the first light, second light, and third light, and
the first light, second light, and third light are each selected from red light, green light, and blue light, and have different colors.

14. The light emitting device according to claim 13, wherein
each of the first, second, and third light-emitting elements is a semiconductor laser element,
the first light, second light, and third light are each selected from red light having a peak emission wavelength of 639 nm±10 nm, green light having a peak emission wavelength of 532 nm±5 nm, and blue light having a peak emission wavelength of 460 nm±10 nm, and have different colors.

15. The light emitting device according to claim 13, further comprising:
a fourth light-emitting element configured to emit a fourth light beam that is infrared light, wherein:
the first, second, third, and fourth light-emitting elements are aligned in a second direction perpendicular to the first direction in a top view in this order, and
the fourth light beam is not combined with the first light, second light, or third light, and a distance between a first location where the first light, second light, and third light are combined, and a second location where a virtual line passing through the first location and parallel to the second direction in the top view intersects with the fourth light beam, is shorter than a distance between the first and third light-emitting elements.

16. The light emitting device according to claim 13, further comprising:
a fourth light-emitting element to emit a fourth light beam that is infrared light, wherein:
the fourth, first, second, and third light-emitting elements are aligned in a second direction perpendicular to the first direction in a top view in this order, and
the fourth light beam is not combined with the first light, second light, or third light, and a distance between a first location where the first light, second light, and third light are combined, and a second location where a virtual line passing through the first location and parallel to the second direction in the top view intersects with the fourth light beam, is longer than a distance between the first and third light-emitting elements.

17. The light emitting device according to claim 13, further comprising:
a fourth light-emitting element to emit a fourth light beam that is infrared light, wherein:
the one or more optical members are configured to combine the first light, second light, third light, and fourth light.
